(19) United States
(12) Patent Application Publication
(10) Pub. No.: US 2025/0351414 A1
(43) Pub. Date: Nov. 13, 2025

(54) SEMICONDUCTOR DEVICE

(71) Applicants: Kabushiki Kaisha Toshiba, Tokyo (JP); Toshiba Electronic Devices & Storage Corporation, Tokyo (JP)

(72) Inventors: Shugo NISHIMURA, Yokohama Kanagawa (JP); Takao NODA, Yokohama Kanagawa (JP); Yasuhiro ISOBE, Narashino Chiba (JP); Yasunobu SAITO, Inagi Tokyo (JP); Toru SUGIYAMA, Musashino Tokyo (JP); Akira YOSHIOKA, Yokohama Kanagawa (JP)

(21) Appl. No.: 19/280,813

(22) Filed: Jul. 25, 2025

Related U.S. Application Data
(63) Continuation of application No. PCT/JP2023/034318, filed on Sep. 21, 2023.

(51) Int. Cl. H10D 30/47; H01L 23/00; H10D 62/85

(52) U.S. Cl. CPC H10D 30/475; H01L 24/48; H10D 62/8503; H01L 2224/4813; H01L 2924/30105

(57) ABSTRACT

A semiconductor device, includes a nitride semiconductor layer; a plurality of source electrodes; a plurality of drain electrodes; a gate electrode being positioned between source and drain electrodes adjacent to each other in a first direction; an insulating layer located on the plurality of source electrodes, the plurality of drain electrodes, and the gate electrode; and a source wiring part located on the insulating layer. The source wiring part includes a plurality of source pad parts electrically connected with the plurality of source electrodes, and a source connecting part connecting two source pad parts adjacent to each other in the first direction. A width in a second direction of the source connecting part is less than widths in the second direction of the plurality of source pad parts.

### CROSS-REFERENCE TO RELATED APPLICATION

This is a continuation application of International Application PCT/JP2023/034318, filed on Sep. 21, 2023; the entire contents of which are incorporated herein by reference.

### FIELD

Embodiments described herein relate generally to a semiconductor device.

### BACKGROUND

A HEMT (High Electron Mobility Transistor) that includes a gallium nitride material is known as a power device.

### BRIEF DESCRIPTION OF THE DRAWINGS

FIG. 1 is a schematic plan view of a semiconductor device of an embodiment;

FIG. 2 is a schematic plan view of an active region of the semiconductor device of the embodiment;

FIG. 3 is an A-A cross-sectional view of FIG. 2;

FIG. 4 is a schematic plan view showing a modified example of the semiconductor device of the embodiment; and

FIG. 5 is a schematic plan view showing another modified example of the semiconductor device of the embodiment.

### DETAILED DESCRIPTION

According to one embodiment, a semiconductor device includes a nitride semiconductor layer; a plurality of source electrodes located on the nitride semiconductor layer, separated from each other in a first direction, and electrically connected with the nitride semiconductor layer, the plurality of source electrodes extending in a second direction crossing the first direction; a plurality of drain electrodes located on the nitride semiconductor layer, separated from each other in the first direction, and electrically connected with the nitride semiconductor layer, the plurality of drain electrodes extending in the second direction; a gate electrode located on the nitride semiconductor layer, the gate electrode extending in the second direction, the gate electrode being positioned between source and drain electrodes adjacent to each other in the first direction among the pluralities of source and drain electrodes; an insulating layer located on the plurality of source electrodes, the plurality of drain electrodes, and the gate electrode; and a source wiring part located on the insulating layer, the source wiring part including a plurality of source pad parts separated from each other in the first direction and electrically connected with the plurality of source electrodes, and a source connecting part connecting two source pad parts adjacent to each other in the first direction among the plurality of source pad parts, a width in the second direction of the source connecting part being less than widths in the second direction of the plurality of source pad parts.

Exemplary embodiments will now be described with reference to the drawings. Similar components in the drawings are marked with like reference numerals.

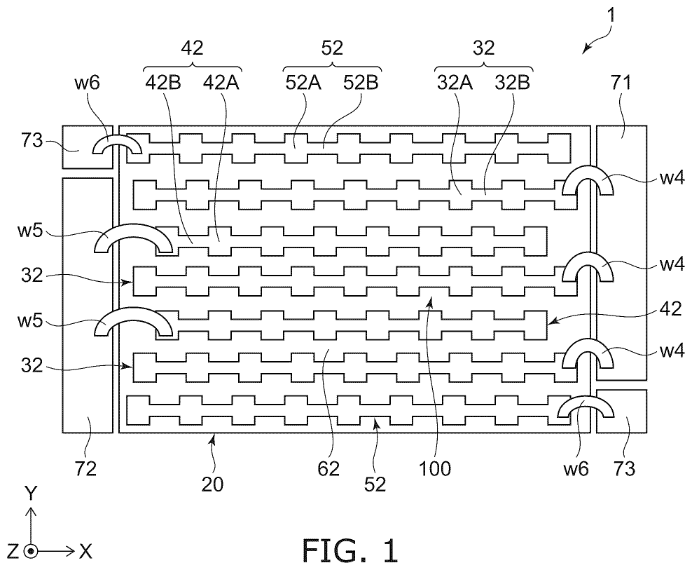

As shown in FIG. 1, a semiconductor device 1 of an embodiment includes a nitride semiconductor layer 20. Two directions crossing each other in a plane parallel to the front surface of the nitride semiconductor layer 20 are referred to as a first direction X and a second direction Y. In the example, the first direction X and the second direction Y are orthogonal to each other. A direction that is orthogonal to the first and second directions X and Y is referred to as a third direction Z.

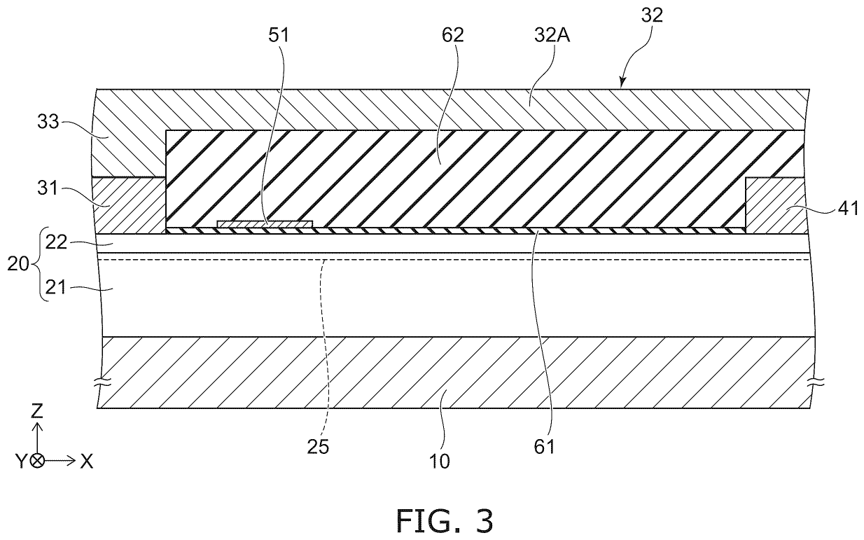

As shown in FIG. 3, the semiconductor device 1 can further include a substrate 10 that supports the nitride semiconductor layer 20. For example, a silicon substrate can be used as the substrate 10. Or, a sapphire substrate may be used as the substrate 10.

The nitride semiconductor layer 20 can include a first layer 21 and a second layer 22. In the third direction Z, the first layer 21 is located on the substrate 10; and the second layer 22 is located on the first layer 21. For example, the first layer 21 and the second layer 22 are grown in this order on the substrate 10 by MOCVD (Metal Organic Chemical Vapor Deposition).

The bandgap of the second layer 22 is wider than the bandgap of the first layer 21. For example, the first layer 21 is a gallium nitride (GaN) layer; and the second layer 22 is an aluminum gallium nitride (AlGaN) layer. A two-dimensional electron gas 25 is distributed in the first layer 21 at the vicinity of the interface with the second layer 22 due to the piezoelectric polarization effect.

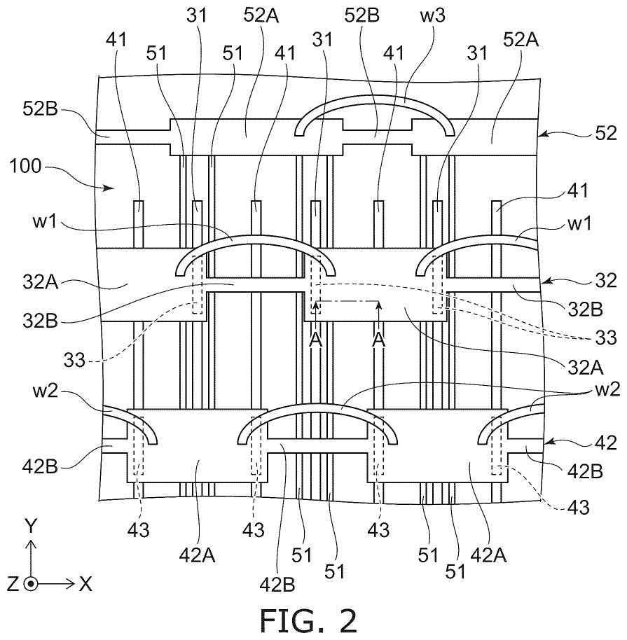

The nitride semiconductor layer 20 includes an active region 100 having the two-dimensional electron gas 25 distributed in the active region 100. The active region 100 is surrounded with an element separating part. For example, the element separating part can be formed by ion implantation. A portion of the active region 100 is shown in FIG. 2. FIG. 3 is a line A-A cross-sectional view of FIG. 2. An insulating layer 62, which is shown in FIG. 3, is not illustrated in FIG. 2. The semiconductor device 1 further includes a source electrode 31, a drain electrode 41, and a gate electrode 51 located on the active region 100 of the nitride semiconductor layer 20.

As shown in FIG. 2, multiple source electrodes 31 are separated from each other in the first direction X and extend in the second direction Y. Multiple drain electrodes 41 are separated from each other in the first direction X and extend in the second direction Y. Multiple gate electrodes 51 are separated from each other in the first direction X and extend in the second direction Y. The source electrodes 31, the drain electrodes 41, and the gate electrodes 51 are separated from each other in the first direction X. One gate electrode 51 is positioned between the source electrode 31 and the drain electrode 41 that are adjacent to each other in the first direction X.

The distance (the drift length) in the first direction X between the drain electrode 41 and the gate electrode 51 is greater than the distance in the first direction X between the source electrode 31 and the gate electrode 51. The breakdown voltage can be increased thereby.

As shown in FIG. 3, a gate insulating film 61 is located on the front surface of the nitride semiconductor layer 20 between the source electrode 31 and the drain electrode 41. The gate electrode 51 is located on the gate insulating film 61. The source electrode 31 and the drain electrode 41 contact the nitride semiconductor layer 20. The gate electrode 51 controls the flow of a current between the drain electrode 41 and the source electrode 31 via the two-dimensional electron gas 25.

The semiconductor device 1 further includes the insulating layer 62 that is located on the source electrode 31, the drain electrode 41, and the gate electrode 51.

As shown in FIG. 1, the semiconductor device 1 further includes a source wiring part 32, a drain wiring part 42, and a gate wiring part 52 located on the insulating layer 62 in the active region 100.

As shown in FIG. 3, the source wiring part 32 is located on the insulating layer 62. Similarly, the drain wiring part 42 and the gate wiring part 52 also are located on the insulating layer 62.

As shown in FIGS. 1 and 2, the source wiring part 32 includes multiple source pad parts 32A separated from each other in the first direction X. The source wiring part 32 also includes a source connecting part 32B connecting two source pad parts 32A adjacent to each other in the first direction X. For example, the source pad part 32A and the source connecting part 32B are alternately arranged in the first direction X.

As shown in FIGS. 2 and 3, the source pad part 32A is electrically connected with the source electrode 31 by a source via 33. The source via 33 is located inside the insulating layer 62 between the source pad part 32A and the source electrode 31.

As shown in FIG. 1, the semiconductor device 1 further includes a first lead 71, a second lead 72, and a third lead 73. For example, the source pad part 32A that is positioned at one end of the source wiring part 32 in the first direction X is connected with the first lead 71 via a fourth wire w4. The source electrode 31 is electrically connected with the first lead 71 by the source via 33, the source wiring part 32, and the fourth wire w4. A source potential (e.g., a ground potential) is applied from an external circuit to the first lead 71.

As shown in FIG. 2, the multiple source pad parts 32A and the multiple source vias 33 are arranged in the first direction X to correspond to the multiple source electrodes 31 arranged in the first direction X. In the example, one source pad part 32A overlaps two source electrodes 31 when viewed in plan as shown in FIG. 2. One source pad part 32A may overlap one, three, or more source electrodes 31 when viewed in plan.

According to the embodiment, by locating the source wiring part 32 for electrically connecting the source electrode 31 with the external circuit on the active region 100, the planar size (the chip size) of the semiconductor device 1 can be reduced.

When the source wiring part 32 is located on the active region 100, the source wiring part 32 crosses the drain electrode 41 and the gate electrode 51 when viewed in plan as shown in FIG. 2. A capacitance Cds is generated between the source wiring part 32 and the drain electrode 41 in the third direction Z at the crossing portion between the source wiring part 32 and the drain electrode 41. A capacitance Cgs is generated between the source wiring part 32 and the gate electrode 51 in the third direction Z at the crossing portion between the source wiring part 32 and the gate electrode 51.

According to the embodiment, the width in the second direction Y of the source connecting part 32B is less than the width in the second direction Y of the source pad part 32A. The area of one source connecting part 32B is less than the area of one source pad part 32A. As a result, the capacitance Cds and the capacitance Cgs can be less than when the source wiring part 32 is formed of only the source pad part 32A. It is sufficient for the source connecting part 32B to be able to electrically connect the adjacent source pad parts 32A to each other; and the source via 33 may not be located under the source connecting part 32B. Accordingly, the width in the second direction Y of the source connecting part 32B can be less than the width in the second direction Y of the source pad part 32A, and/or the area of the source connecting part 32B can be less than the area of the source pad part 32A. Or, the source via 33 may be located under the source connecting part 32B.

According to the embodiment, the capacitance Cds and the capacitance Cgs can be reduced by including the source connecting part 32B having a smaller width and/or area than the source pad part 32A while easily ensuring the electrical connection between the source electrode 31 and the first lead 71 at the source pad part 32A.

As shown in FIGS. 1 and 2, the drain wiring part 42 includes multiple drain pad parts 42A separated from each other in the first direction X. The drain wiring part 42 also includes a drain connecting part 42B connecting two drain pad parts 42A adjacent to each other in the first direction X. For example, the drain pad part 42A and the drain connecting part 42B are alternately arranged in the first direction X.

As shown in FIG. 2, the drain pad part 42A is electrically connected with the drain electrode 41 by a drain via 43. The drain via 43 is located inside the insulating layer 62 between the drain pad part 42A and the drain electrode 41.

As shown in FIG. 1, for example, the drain pad part 42A that is positioned at one end of the drain wiring part 42 in the first direction X is connected with the second lead 72 via a fifth wire w5. The drain electrode 41 is electrically connected with the second lead 72 by the drain via 43, the drain wiring part 42, and the fifth wire w5. A drain potential is applied from the external circuit to the second lead 72.

As shown in FIG. 2, the multiple drain pad parts 42A and the multiple drain vias 43 are arranged in the first direction X to correspond to the multiple drain electrodes 41 arranged in the first direction X. In the example when viewed in plan as shown in FIG. 2, one drain pad part 42A overlaps two drain electrodes 41. When viewed in plan, one drain pad part 42A may overlap one, three, or more drain electrodes 41.

By locating the drain wiring part 42 for electrically connecting the drain electrode 41 to the external circuit on the active region 100, the planar size (the chip size) of the semiconductor device 1 can be reduced.

By locating the drain wiring part 42 on the active region 100, the drain wiring part 42 crosses the source electrode 31 and the gate electrode 51 when viewed in plan as shown in FIG. 2. The capacitance Cds is generated between the drain wiring part 42 and the source electrode 31 in the third direction Z at the crossing portion between the drain wiring part 42 and the source electrode 31. A capacitance Cgd is generated between the drain wiring part 42 and the gate electrode 51 in the third direction Z at the crossing portion between the drain wiring part 42 and the gate electrode 51.

According to the embodiment, the width in the second direction Y of the drain connecting part 42B is less than the width in the second direction Y of the drain pad part 42A. The area of one drain connecting part 42B is less than the area of one drain pad part 42A. As a result, the capacitance Cds and the capacitance Cgd can be less than when the drain wiring part 42 is formed of only the drain pad part 42A. It is sufficient for the drain connecting part 42B to be able to electrically connect the adjacent drain pad parts 42A to each other; and the drain via 43 may not be located under the drain connecting part 42B. Accordingly, the width in the second direction Y of the drain connecting part 42B can be less than the width in the second direction Y of the drain pad part 42A, and/or the area of the drain connecting part 42B can be less than the area of the drain pad part 42A. Or, the drain via 43 may be located under the drain connecting part 42B.

According to the embodiment, the capacitance Cds and the capacitance Cgd can be reduced by including the drain connecting part 42B having a smaller width and/or area than the drain pad part 42A while easily ensuring the electrical connection between the drain electrode 41 and the second lead 72 at the drain pad part 42A.

As shown in FIG. 1, the semiconductor device 1 includes multiple source wiring parts 32 and multiple drain wiring parts 42. The multiple source wiring parts 32 and the multiple drain wiring parts 42 include the source wiring part 32 and the drain wiring part 42 alternately arranged in the second direction Y. By alternately arranging the source wiring part 32 and the drain wiring part 42 in the second direction Y, the source wiring parts 32 can be electrically connected to the source electrodes 31 extending in the second direction Y without bias in the second direction Y; and current distribution bias of the source electrode 31 can be reduced. Similarly, the drain wiring parts 42 can be electrically connected to the drain electrodes 41 extending in the second direction Y without bias in the second direction Y; and current distribution bias of the drain electrode 41 can be reduced. The multiple source wiring parts 32 and the multiple drain wiring parts 42 may not be alternately arranged.

The position in the first direction X of the source pad part 32A for connecting with the source electrode 31 and the position in the first direction X of the drain pad part 42A for connecting with the drain electrode 41 are shifted in the first direction X according to the positions in the first direction X of the source electrode 31 and the drain electrode 41. In other words, the source pad part 32A and the drain connecting part 42B are adjacent to each other in the second direction Y; and the drain pad part 42A and the source connecting part 32B are adjacent to each other in the second direction Y. The source pad part 32A and the drain connecting part 42B may not be adjacent to each other in the second direction Y; and the drain pad part 42A and the source connecting part 32B may not be adjacent to each other in the second direction Y.

As shown in FIGS. 1 and 2, the gate wiring part 52 includes multiple gate pad parts 52A separated from each other in the first direction X. The gate pad parts 52A are electrically connected with the gate electrodes 51. The gate wiring part 52 includes a gate connecting part 52B connecting two gate pad parts 52A adjacent to each other in the first direction X. For example, the gate pad part 52A and the gate connecting part 52B are alternately arranged in the first direction X.

As shown in FIG. 1, for example, the gate pad part 52A that is positioned at one end of the gate wiring part 52 in the first direction X is connected with the third lead 73 via a sixth wire w6. The gate electrode 51 is electrically connected with the third lead 73 via the gate wiring part 52 and the sixth wire w6. The gate potential is applied from the external circuit to the third lead 73.

The current that flows in the gate electrode 51 is less than the current flowing in the drain electrode 41 and the source electrode 31. Therefore, the number of the gate wiring parts 52 may be less than the number of the source wiring parts 32; and the number of the gate wiring parts 52 may be less than the number of the drain wiring parts 42. For example, as shown in FIG. 1, the two gate wiring parts 52 can be arranged at two ends in the second direction Y in the active region 100. The multiple source wiring parts 32 and the multiple drain wiring parts 42 are located between the two gate wiring parts 52 separated in the second direction Y. In such a case, when viewed in plan as shown in FIG. 2, it is unnecessary for the gate wiring part 52 to cross the source electrode 31 and the drain electrode 41. As a result, the capacitance between the gate wiring part 52 and the source electrode 31 and the capacitance between the gate wiring part 52 and the drain electrode 41 can be reduced.

The planar size (the chip size) of the semiconductor device 1 can be reduced by locating the gate wiring part 52 for electrically connecting the gate electrode 51 with the external circuit on the active region 100.

When the gate wiring part 52 crosses the source electrode 31 and the drain electrode 41 when viewed in plan, the capacitance Cgs between the gate wiring part 52 and the source electrode 31 in the third direction Z is generated at the crossing portion between the gate wiring part 52 and the source electrode 31. The capacitance Cgd is generated between the gate wiring part 52 and the drain electrode 41 in the third direction Z at the crossing portion between the gate wiring part 52 and the drain electrode 41.

According to the embodiment, the width in the second direction Y of the gate connecting part 52B is less than the width in the second direction Y of the gate pad part 52A. The area of one gate connecting part 52B is less than the area of one gate pad part 52A. As a result, the capacitance Cgs and the capacitance Cgd can be less than when the gate wiring part 52 is formed of only the gate pad part 52A.

According to the embodiment, the capacitance Cgs and the capacitance Cgd can be reduced by including the gate connecting part 52B having a smaller width and/or area than the gate pad part 52A while easily ensuring the electrical connection between the gate electrode 51 and the third lead 73 at the gate pad part 52A.

As shown in FIG. 2, the semiconductor device 1 can further include a first wire w1 connecting two source pad parts 32A adjacent to each other in the first direction X. The wiring resistance of the source wiring part 32 can be reduced by connecting two mutually-adjacent source pad parts 32A by the first wire w1 and the source connecting part 32B. The multiple source pad parts 32A may be electrically connected to each other by forming bumps on the multiple source pad parts 32A and by connecting the multiple bumps with an upper layer wiring part.

The semiconductor device 1 can further include a second wire w2 connecting two drain pad parts 42A adjacent to each other in the first direction X. The wiring resistance of the drain wiring part 42 can be reduced by connecting two mutually-adjacent drain pad parts 42A by the second wire w2 and the drain connecting part 42B. The multiple drain pad parts 42A may be electrically connected to each other by forming bumps on the multiple drain pad parts 42A and by connecting the multiple bumps with an upper layer wiring part.

The semiconductor device 1 can further include a third wire w3 connecting two gate pad parts 52A adjacent to each other in the first direction X. The wiring resistance of the gate wiring part 52 can be reduced by connecting two mutually-adjacent gate pad parts 52A by the third wire w3 and the gate connecting part 52B. The multiple gate pad parts 52A may be electrically connected to each other by forming bumps on the multiple gate pad parts 52A and by connecting the multiple bumps with an upper layer wiring part.

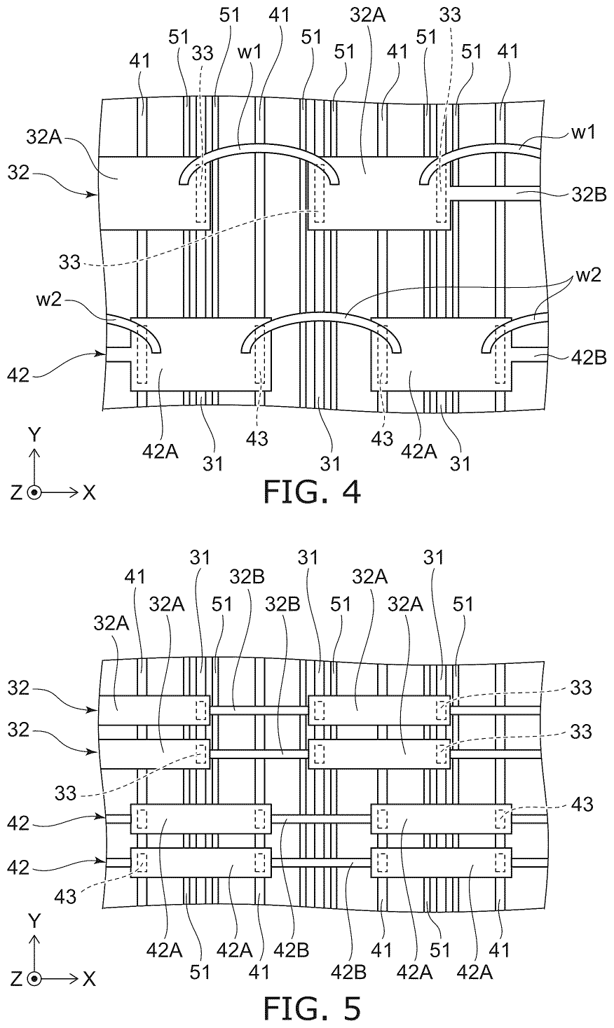

As shown in FIG. 4, the source wiring part 32 may include at least two source pad parts 32A not connected by the source connecting part 32B. The two source pad parts 32A that are not connected by the source connecting part 32B are electrically connected by the first wire w1. The capacitance Cds and the capacitance Cgs described above are not generated where the source connecting part 32B is not located.

The drain wiring part 42 may include at least two drain pad parts 42A not connected by the drain connecting part 42B. The two drain pad parts 42A that are not connected by the drain connecting part 42B are electrically connected by the second wire w2. The capacitance Cds and the capacitance Cgd described above are not generated where the drain connecting part 42B is not located.

The gate wiring part 52 may include at least two gate pad parts 52A not connected by the gate connecting part 52B. The two gate pad parts 52A that are not connected by the gate connecting part 52B are electrically connected by the third wire w3. The capacitance Cgs and the capacitance Cgd described above are not generated where the gate connecting part 52B is not located.

As shown in FIG. 5, the multiple source wiring parts 32 may include at least two source wiring parts 32 arranged adjacent to each other in the second direction Y so that the drain wiring part 42 and the gate wiring part 52 are not positioned between the two source wiring parts 32.

The multiple drain wiring parts 42 may include at least two drain wiring parts 42 arranged adjacent to each other in the second direction Y so that the source wiring part 32 and the gate wiring part 52 are not positioned between the two drain wiring parts 42.

The multiple gate wiring parts 52 may include at least two gate wiring parts 52 arranged adjacent to each other in the second direction Y so that the source wiring part 32 and the drain wiring part 42 are not positioned between the two gate wiring parts 52.

The source wiring part 32, the drain wiring part 42, and the gate wiring part 52 are not limited to being positioned on the active region 100; however, the planar size and the capacitance can be reduced by positioning at least one wiring part among the source wiring part 32, the drain wiring part 42, and the gate wiring part 52 on the active region 100.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor device, comprising:
a nitride semiconductor layer;
a plurality of source electrodes located on the nitride semiconductor layer, separated from each other in a first direction, and electrically connected with the nitride semiconductor layer, the plurality of source electrodes extending in a second direction crossing the first direction;
a plurality of drain electrodes located on the nitride semiconductor layer, separated from each other in the first direction, and electrically connected with the nitride semiconductor layer, the plurality of drain electrodes extending in the second direction;
a gate electrode located on the nitride semiconductor layer, the gate electrode extending in the second direction, the gate electrode being positioned between source and drain electrodes adjacent to each other in the first direction among the pluralities of source and drain electrodes;
an insulating layer located on the plurality of source electrodes, the plurality of drain electrodes, and the gate electrode; and
a source wiring part located on the insulating layer, the source wiring part including
a plurality of source pad parts separated from each other in the first direction and electrically connected with the plurality of source electrodes, and
a source connecting part connecting two source pad parts adjacent to each other in the first direction among the plurality of source pad parts,
a width in the second direction of the source connecting part being less than widths in the second direction of the plurality of source pad parts.

2. The device according to claim 1, wherein
the nitride semiconductor layer includes an active region having a two-dimensional electron gas distributed in the active region, and
the plurality of source electrodes, the plurality of drain electrodes, the gate electrode, and the source wiring part are located on the active region.

3. The device according to claim 1, wherein
the source wiring part crosses at least one of the plurality of drain electrodes when viewed in plan.

4. The device according to claim 1, wherein
the source wiring part includes at least two source pad parts not connected by the source connecting part.

5. The device according to claim 1, further comprising:
a first wire connecting the two source pad parts adjacent to each other in the first direction among the plurality of source pad parts.

6. The device according to claim 1, further comprising:
a drain wiring part located on the insulating layer, the drain wiring part including
a plurality of drain pad parts separated from each other in the first direction and electrically connected with the plurality of drain electrodes, and
a drain connecting part connecting two drain pad parts adjacent to each other in the first direction among the plurality of drain pad parts,
a width in the second direction of the drain connecting part being less than widths in the second direction of the plurality of drain pad parts.

7. The device according to claim 6, wherein
the drain wiring part crosses at least one of the plurality of source electrodes when viewed in plan.

8. The device according to claim 6, comprising:
a plurality of the source wiring parts and a plurality of the drain wiring parts,
the plurality of source wiring parts and the plurality of drain wiring parts including at least one source wiring part and at least one drain wiring part alternately arranged in the second direction.

9. The device according to claim 6, comprising:
a plurality of the source wiring parts,
the plurality of source wiring parts including at least two source wiring parts adjacent to each other in the second direction,
none of the plurality of drain wiring parts being positioned between the at least two source wiring parts.

10. The device according to claim 6, comprising:
a plurality of the drain wiring parts,
the plurality of drain wiring parts including at least two drain wiring parts adjacent to each other in the second direction,
none of the plurality of source wiring parts being positioned between the at least two drain wiring parts.

11. The device according to claim 6, wherein
the drain connecting part and at least one of the plurality of source pad parts are adjacent to each other in the second direction, and
the source connecting part and at least one of the plurality of drain pad parts are adjacent to each other in the second direction.

12. The device according to claim 1, further comprising:
a gate wiring part located on the insulating layer, the gate wiring part including
a plurality of gate pad parts separated from each other in the first direction and electrically connected with a plurality of the gate electrodes, and
a gate connecting part connecting two gate pad parts adjacent to each other in the first direction among the plurality of gate pad parts,
a width in the second direction of the gate connecting part being less than widths in the second direction of the plurality of gate pad parts.

13. A semiconductor device, comprising:
a nitride semiconductor layer;
a plurality of source electrodes located on the nitride semiconductor layer, separated from each other in a first direction, and electrically connected with the nitride semiconductor layer, the plurality of source electrodes extending in a second direction crossing the first direction;
a plurality of drain electrodes located on the nitride semiconductor layer, separated from each other in the first direction, and electrically connected with the nitride semiconductor layer, the plurality of drain electrodes extending in the second direction;
a gate electrode located on the nitride semiconductor layer, the gate electrode extending in the second direction, the gate electrode being positioned between source and drain electrodes adjacent to each other in the first direction among the pluralities of source and drain electrodes;
an insulating layer located on the plurality of source electrodes, the plurality of drain electrodes, and the gate electrode; and
a drain wiring part located on the insulating layer, the drain wiring part including
a plurality of drain pad parts separated from each other in the first direction and electrically connected with the plurality of drain electrodes, and
a drain connecting part connecting two drain pad parts adjacent to each other in the first direction among the plurality of drain pad parts,
a width in the second direction of the drain connecting part being less than widths in the second direction of the plurality of drain pad parts.

14. The device according to claim 13, wherein
the nitride semiconductor layer includes an active region having a two-dimensional electron gas distributed in the active region, and
the plurality of source electrodes, the plurality of drain electrodes, the gate electrode, and the drain wiring part are located on the active region.

15. The device according to claim 13, wherein
the drain wiring part crosses at least one of the plurality of source electrodes when viewed in plan.

16. The device according to claim 13, wherein
the drain wiring part includes at least two drain pad parts not connected by the drain connecting part.

17. The device according to claim 13, further comprising:
a second wire connecting the two drain pad parts adjacent to each other in the first direction among the plurality of drain pad parts.

18. The device according to claim 13, further comprising:
a gate wiring part located on the insulating layer, the gate wiring part including
a plurality of gate pad parts separated from each other in the first direction and electrically connected with a plurality of the gate electrodes, and
a gate connecting part connecting two gate pad parts adjacent to each other in the first direction among the plurality of gate pad parts,
a width in the second direction of the gate connecting part being less than widths in the second direction of the plurality of gate pad parts.

19. The device according to claim 18, comprising:
two of the gate wiring parts separated from each other in the second direction,
a plurality of the source wiring parts and a plurality of the drain wiring parts being located between the two of the gate wiring parts.

20. A semiconductor device, comprising:
a nitride semiconductor layer;
a plurality of source electrodes located on the nitride semiconductor layer, separated from each other in a first direction, and electrically connected with the nitride semiconductor layer, the plurality of source electrodes extending in a second direction crossing the first direction;
a plurality of drain electrodes located on the nitride semiconductor layer, separated from each other in the first direction, and electrically connected with the nitride semiconductor layer, the plurality of drain electrodes extending in the second direction;
a gate electrode located on the nitride semiconductor layer, the gate electrode extending in the second direction, the gate electrode being positioned between source and drain electrodes adjacent to each other in the first direction among the pluralities of source and drain electrodes;
an insulating layer located on the plurality of source electrodes, the plurality of drain electrodes, and the gate electrode; and
a gate wiring part located on the insulating layer, the gate wiring part including
a plurality of gate pad parts separated from each other in the first direction and electrically connected with a plurality of the gate electrodes, and
a gate connecting part connecting two gate pad parts adjacent to each other in the first direction among the plurality of gate pad parts,
a width in the second direction of the gate connecting part being less than widths in the second direction of the plurality of gate pad parts.

21. The device according to claim 20, wherein
the nitride semiconductor layer includes an active region having a two-dimensional electron gas distributed in the active region, and
the plurality of source electrodes, the plurality of drain electrodes, the gate electrode, and the gate wiring part are located on the active region.

22. The device according to claim 20, wherein
the gate wiring part includes at least two gate pad parts not connected by the gate connecting part.

23. The device according to claim 20, further comprising:
a third wire connecting the two gate pad parts adjacent to each other in the first direction among the plurality of gate pad parts.
